(19) United States
(12) Patent Application Publication
(10) Pub. No.: US 2015/0318280 A1
(43) Pub. Date: Nov. 5, 2015

(54) WIDE-BOTTOM CONTACT FOR NON-PLANAR SEMICONDUCTOR STRUCTURE AND METHOD OF MAKING SAME

(71) Applicant: GLOBALFOUNDRIES INC., Grand Cayman (KY)

(72) Inventors: Seong Yeol MUN, Cohoes, NY (US); Bumhwan JEON, Rexford, NY (US); Kijik LEE, Gansevoort, NY (US)

(73) Assignee: GLOBALFOUNDRIES INC., Grand Cayman (KY)

(21) Appl. No.: 14/266,278

(22) Filed: Apr. 30, 2014

(51) Int. Cl. H01L 27/088; H01L 21/768; H01L 29/66; H01L 21/285; H01L 29/417; H01L 21/8234; H01L 21/3213

(52) U.S. Cl. CPC H01L 27/0886; H01L 21/823431; H01L 21/823475; H01L 21/76897; H01L 21/32133; H01L 21/28518; H01L 29/41791; H01L 29/41783; H01L 29/665; H01L 29/66795

(57) ABSTRACT

A wide-bottom contact to epitaxial structures in a non-planar semiconductor structure is provided. A starting structure includes a non-planar semiconductor structure, the structure including a semiconductor substrate, fins coupled to the substrate, and epitaxial structures (e.g., diamond-shaped silicon epitaxy) on the fins. Trenches to the epitaxial structures with roughly vertical sidewalls are created from a field oxide and photoresist. Silicide is formed on the epitaxial structures, and bottom contact portions (of metal, e.g., tungsten) are conformally created on the silicide. The vertical sidewalls allow for a wider bottom. Contact bodies are then formed on the bottom contact portions.

### BACKGROUND OF THE INVENTION

1. Technical Field

The present invention generally relates to contacts for non-planar semiconductor structures, and in particular, to contacts having a bottom that is wider than the body of the contact where the contact body meets the contact bottom.

2. Background Information

As semiconductor device sizes continue to shrink, the contacts used in them also shrink. Typical contacts used in non-planar semiconductor devices are roughly V-shaped with a fixed size at the top (the critical dimension), and, as they shrink, the area of the contact at the bottom of the V-shape may not have enough surface area to provide the desired performance, which increases contact resistance. In addition, the smaller area of the trench bottom that is filled with the contact material after creating silicide makes it difficult to create the silicide in the active area below.

Thus, a need exists for better contacts in non-planar devices that do not increase the critical dimension of the contact.

### SUMMARY OF THE INVENTION

The shortcomings of the prior art are overcome and additional advantages are provided through the provision, in one aspect, of a method of forming a wide-bottom contact in a non-planar semiconductor structure. The method includes providing a non-planar semiconductor structure, the structure including a semiconductor substrate and one or more raised semiconductor structures coupled to the substrate. The method further includes forming at least one bottom contact portion above and electrically coupled to the one or more raised semiconductor structures, and forming at least one contact body on the at least one bottom contact portion. The at least one bottom contact portion is wider than the at least one contact body where the at least one bottom contact portion and the at least one contact body meet.

In accordance with another aspect, a non-planar semiconductor structure is provided. The structure includes a semiconductor substrate, one or more raised semiconductor structures coupled to the substrate, at least one gate structure encompassing portions of the one or more raised semiconductor structures, and a layer of filler material on either side of the at least one gate structure and above the one or more raised semiconductor structures. A top surface of the filler material layer is situated below that of the at least one gate structure.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a top-down view of one simplified example of a non-planar semiconductor structure in accordance with one or more aspects of the present invention.

FIG. 2 is a simplified cross-sectional view of one example of an active portion of the raised semiconductor structure of FIG. 1 with a wide-bottom contact portion thereon.

FIG. 3 depicts the structure of FIG. 2 with a contact body on the bottom contact portion.

FIG. 4 is a partial, more detailed cross-sectional view of the non-planar semiconductor structure of FIGS. 1-3.

FIG. 5 depicts the non-planar semiconductor structure of FIG. 4 after the creation of trenches for silicidation.

FIG. 6 depicts the non-planar semiconductor structure of FIG. 4 after silicidation.

FIG. 7 depicts the non-planar semiconductor structure of FIG. 6 after blanket deposition of an electrical contact material.

FIG. 8 depicts the non-planar semiconductor structure of FIG. 7 after etching the electrical contact material to create bottom contact portions on the silicide.

FIG. 9 depicts the non-planar semiconductor structure of FIG. 8 after creating contact bodies above the bottom contact portions, completing the contacts.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

Reference is made below to the drawings, which are not drawn to scale for ease of understanding, wherein the same reference numbers are used throughout different figures to designate the same or similar components.

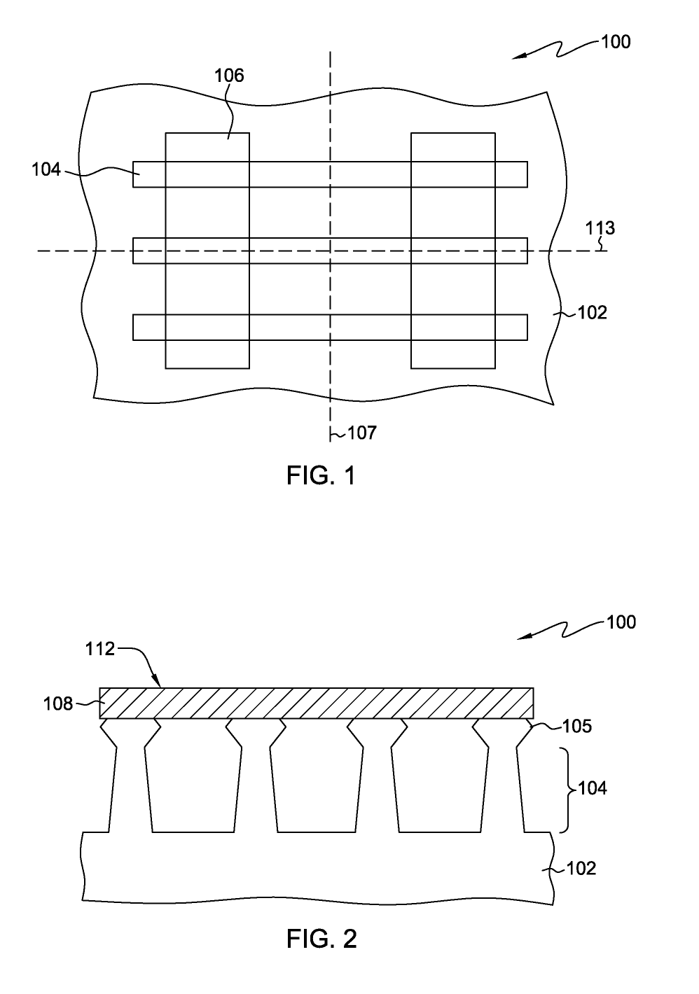

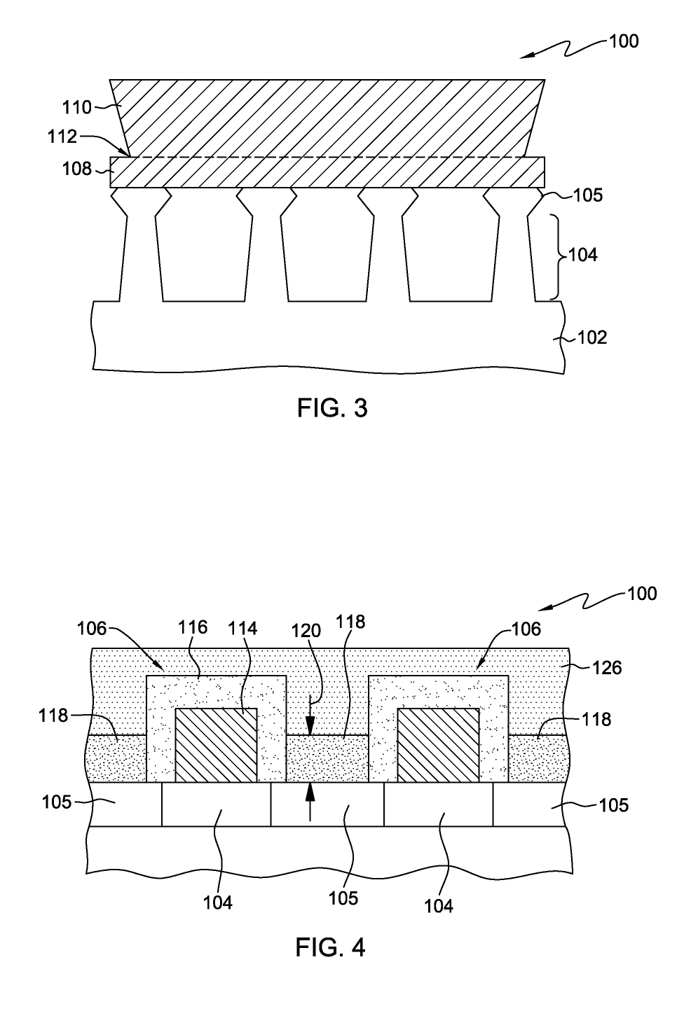

FIG. 1 is a simplified top-down view of one example of a non-planar semiconductor structure 100, e.g., non-planar transistor(s), in accordance with aspects of the invention. The structure includes a semiconductor substrate 102, e.g., a silicon-based wafer, a plurality of raised semiconductor structures 104 and a plurality of gate structures 106 encompassing active regions (e.g., channel regions) of the raised structures. As used herein, the term “raised semiconductor structure” refers to a structure that is raised with respect to the substrate (e.g., a “fin”), creating a non-planar structure. In one example, the raised structures have been etched from the same bulk semiconductor as the substrate. The semiconductor material for the substrate may include any suitable semiconductor material, for example, silicon (Si), gallium arsenide (GaAs) or indium phosphide (InP). In addition, the substrate may be a bulk substrate (e.g., wafer). Although only three raised structures and two gate structures are shown in FIG. 1 for ease of understanding, it will be understood there could be (and, typically, would be) many more of each. As will be explained in more detail with respect to FIG. 3, one or more epitaxial structure(s) may be grown on a top surface of one or more of the raised semiconductor structure(s).

FIGS. 2 and 3 are simplified cross-sectional views of the non-planar semiconductor structure 100 of FIG. 1, taken along line 107 in FIG. 1 over a source or drain region, showing a wide-bottom contact portion 108 (FIG. 2) and finished contact with contact body 110 on the bottom contact portion (FIG. 3). As shown in FIG. 2, optional epitaxial structures 105 have been grown on raised semiconductor structures 104 in source/drain regions of the structure. Where present, the epitaxial structure(s) may include a single epitaxial material, for example, silicon, germanium, or a combination of semiconductor materials, for example, silicon germanium. More broadly, the epitaxial structure(s) may include one or more semiconductor materials suitable for the application from Groups III-V of the Periodic Table of Elements. In the example, a silicon-based epitaxial material is used, which, as one skilled in the art will know, naturally grows into a diamond shape. Where, for example, the structure 100 includes FinFETs (Field Effect Transistors with fin-shaped raised structures), the epitaxial structures may include silicon nitride for n-type fins and silicon phosphorus for p-type fins.

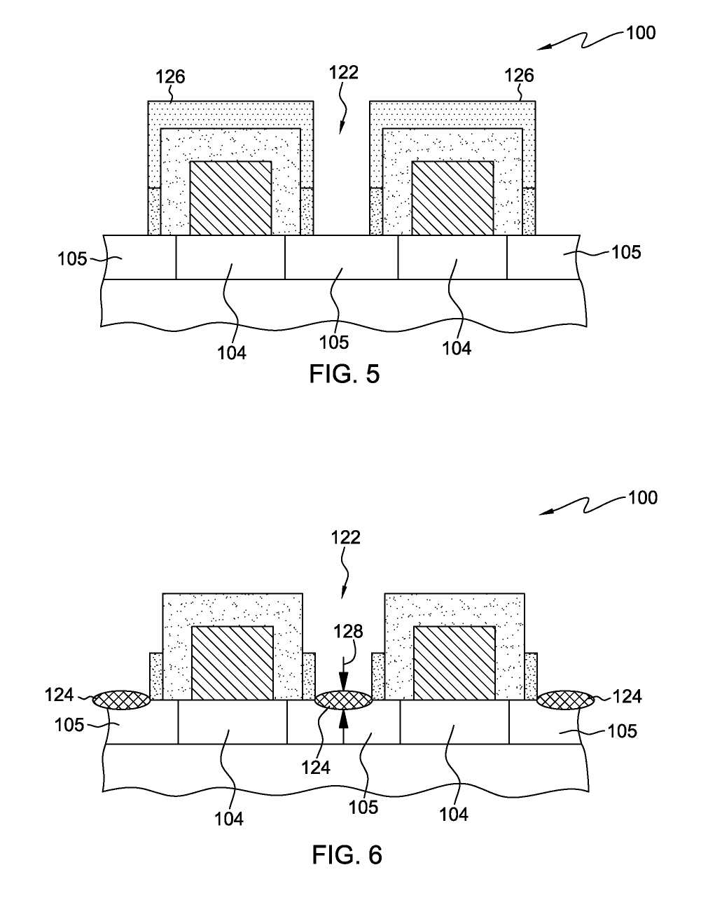

FIG. 4 is a partial, more detailed cross-sectional view of the non-planar semiconductor structure 100 of FIGS. 1-3, taken along line 113 of FIG. 1. The non-planar structure below the epitaxial structures has been omitted for ease of understanding, however, it will be understood that the raised structures and substrate are present. As shown in FIG. 4, the gate structures 106 may include, for example, a gate metal 114 covered with a layer 116 of a protective material or cap. In one example, the protective material includes a nitride, e.g., silicon nitride. Covering the epitaxial structures 105 is a layer 118 of one or more filler materials, for example, an oxide. In one example, the oxide includes a field oxide deposited via conventional chemical vapor deposition (CVD). The layer of filler material preferably has a thickness 120 of about 50 nm to about 100 nm. Note that the filler material height is less than the gate height, which will promote trenches having more vertical sidewalls, as subsequently described with respect to FIG. 5.

FIG. 5 depicts the structure 100 of FIG. 4 after creation of trenches 122 for silicidation. In one example, a blanket layer of lithographic blocking material 126 (e.g., photoresist) is deposited over the structure of FIG. 4. The blanket layer and filler layer may then be etched to create trenches 122. In one example, a dry etch is used to etch both layers. Note that trenches 122 have vertical walls, rather than angled walls of a conventional V-shaped trench. This provides a wider area for silicidation at the bottom of the trench, as compared to a conventional V-shaped trench, as the trench typically has a design size limitation at the top.

FIG. 6 depicts the structure 100 of FIG. 5 after removal of the remaining lithographic blocking material (126, FIG. 5), which may be accomplished, for example, using Reactive Ion Etching (RIE) with, e.g., an oxygen plasma. In practice, the structure would typically also be cleaned prior so silicidation. Silicide 124 (also referred to as “salicide,” which is simply silicide in a self-aligned scenario) may then be created on the epitaxial structures 105. In one example, the silicide is created by deposition and anneal, for example, titanium silicide may be created by depositing a bottom layer of titanium and a top layer of titanium nitride (e.g., about 7.5 nm and about 3.2 nm thick, respectively), then annealing by rapid thermal anneal (RTA), e.g., at a temperature of about 620 degrees Celsius for about 20 seconds to form titanium silicide. In that example, one could expect a silicide (TiSi) thickness 128 of about 9 nm to about 12 nm, which is thicker than conventionally possible, due to the size of the trench.

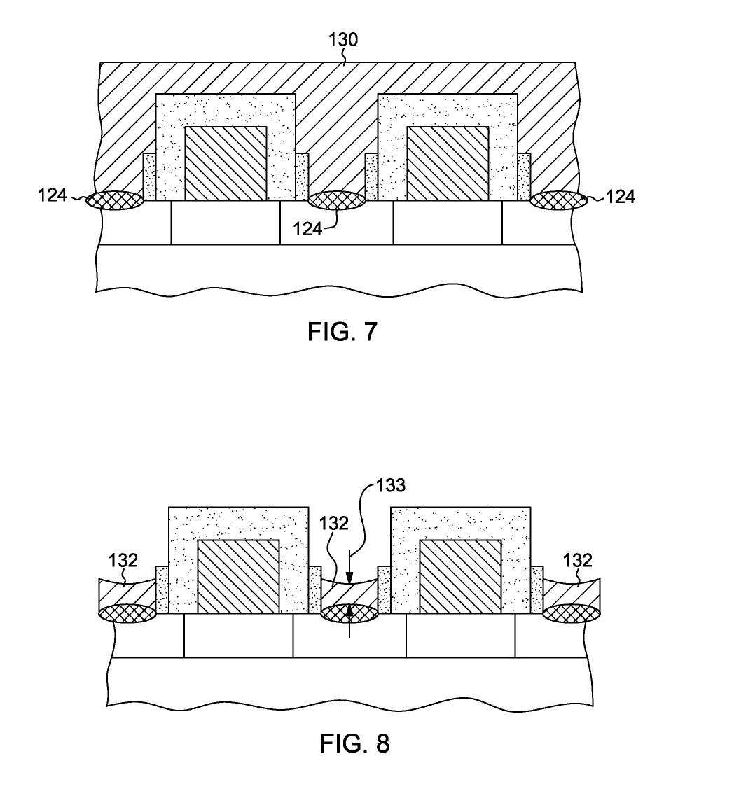

FIG. 7 depicts the structure of FIG. 6 after blanket deposition of a layer 130 of an electrical contact material. The purpose for the electrical contact material is to provide bottom contact portions for electrical contacts to the silicide on the epitaxial structures. In one example, the lithographic blocking material can be removed using oxygen plasma. After removal of the lithographic blocking material, blanket deposition of electrical contact material layer 130 can be accomplished by, for example, using nucleation and a CVD process. In one example, the electrical contact material is tungsten. Tungsten hexafluoride (WF₆) and Silane (SiH₄) may be used for nucleation, and growth of tungsten may be accomplished in an atmosphere of WF₆ and 3H₂ at a temperature of about 415 degrees Celsius until reaching a desired thickness. A tungsten thickness of about 50 nm to about 200 nm can be achieved.

FIG. 8 depicts the structure of FIG. 7 after etching of the blanket layer 130 of electrical contact material to leave a bottom contact portion 132 having a thickness 133 of about 10 nm to about 40 nm, and a width of about 28 nm to about 32 nm. Note that the bottom contact portion is wider than conventionally possible (typically about 19 nm), since conventionally, a V-shaped trench would be used to create the contact, whereas more vertical walls for the trench are used in the present invention, as described with respect to FIG. 5. In one example, the etch may be a dry etch, for example, using reactive-ion etching with a plasma of, e.g., tetrafluoromethane (CF₄), trifluoromethane (R23) (CHF₃), octafluorocyclobutane (C₄F₈) or oxygen gas (O₂).

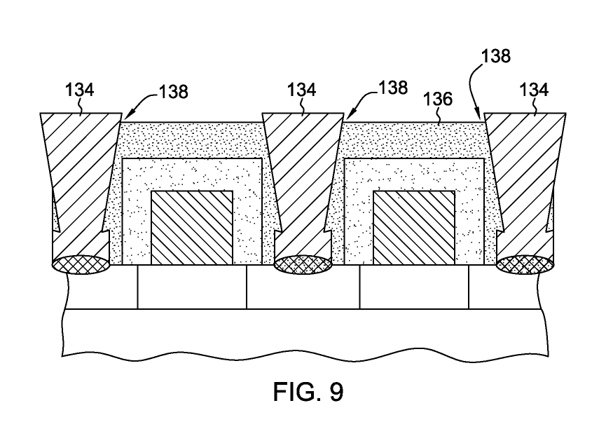

FIG. 9 depicts the structure of FIG. 8 after creation of body contact portion(s) 134 on the bottom contact portion(s) 132. In one example, this may be accomplished by blanket deposition of a filler material 136, etching to create trenches 138, and filling the trenches with an electrical contact material. Preferably, the electrical contact material is the same as that of the bottom contact portions. The filler material may be, for example, an interlayer dielectric, e.g., plasma-enhanced tetraethyl orthosilicate (Si(OC₂H₅)₄) or “PE-TEOS,” and has a thickness of about 70 nm. The filler material may be planarized using, for example, a chemical-mechanical polishing (CMP) technique. Etching the filler material to create the trenches may be accomplished by, for example, a dry etch using reactive-ion etching with a plasma of, e.g., tetrafluoromethane (CF₄), trifluoromethane (R23) (CHF₃), octafluorocyclobutane (C₄F₈) or oxygen gas (O₂). Filling of the trenches with an electrical contact material may be accomplished by, for example, blanket deposition of electrical contact material 134, which may be accomplished, for example, using a CVD process. In one example, the electrical contact material is tungsten, and tungsten hexafluoride (WF₆) and Silane (SiH₄) is used for nucleation, and growth of tungsten is accomplished in an atmosphere of WF₆ and 3H₂ at a temperature of about 415 degrees Celsius until reaching a desired thickness. A tungsten thickness of about 200 nm can be achieved. Excess electrical contact material may be removed, for example, using CMP.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a non-planar semiconductor structure, the structure comprising a semiconductor substrate and one or more raised semiconductor structures coupled to the substrate;
forming at least one bottom contact portion above and electrically coupled to the one or more raised semiconductor structures; and
forming at least one contact body on the at least one bottom contact portion, wherein the at least one bottom contact portion is wider than the at least one contact body where the at least one bottom contact portion and the at least one contact body meet.

2. The method of claim 1, wherein the semiconductor structure further comprises a trench having roughly vertical sidewalls above the one or more raised semiconductor structures, the method further comprising, prior to forming the at least one bottom contact portion, forming silicide on a top surface of the one or more raised semiconductor structures, and wherein the at least one bottom contact portion is formed on the silicide.

3. The method of claim 2, wherein the trench is formed in part by filler material sidewall portions, and wherein forming the at least one bottom contact portion comprises conformally filling an area between the filler material wall portions on the silicide with a contact material.

4. The method of claim 3, wherein the filling comprises:
blanketly depositing the contact material over the semiconductor structure; and
etching to remove the contact material except for the at least one bottom contact portion.

5. The method of claim 3, wherein forming the contact body comprises:
blanketly depositing a filler material over the semiconductor structure after forming the at least one bottom contact portion;
etching at least one contact body trench selective to the contact material to expose the at least one bottom contact portion; and
filling the at least one contact body trench with the contact material.

6. The method of claim 5, further comprising removing excess contact material after filling the at least one new trench.

7. The method of claim 1, wherein the semiconductor structure further comprises silicide on a top surface of the one or more raised semiconductor structures, and wherein forming the at least one bottom contact portion comprises conformally forming the at least one bottom contact portion on the silicide.

8. The method of claim 7, wherein forming the contact body comprises:
blanketly depositing a filler material over the semiconductor structure after conformally forming the at least one bottom contact portion;
etching at least one contact body trench selective to the contact material to expose the at least one bottom contact portion; and
filling the at least one contact body trench with another contact material.

9. The method of claim 7, wherein the another contact material is a same contact material as that of the at least one bottom contact portion.

10. The method of claim 1, wherein the non-planar semiconductor structure further comprises one or more semiconductor epitaxial structures on the one or more raised semiconductor structures, and wherein the forming comprises forming at least one bottom contact portion above and electrically coupled to the one or more epitaxial structures.

11. A non-planar semiconductor structure, comprising:
a semiconductor substrate;
one or more raised semiconductor structures coupled to the substrate;
at least one gate structure encompassing portions of the one or more raised semiconductor structures; and
a layer of filler material on either side of the at least one gate structure and above the one or more raised semiconductor structures, wherein a top surface of the filler material layer is situated below that of the at least one gate structure.

12. The non-planar semiconductor structure of claim 11, wherein the filler material layer has a thickness of about 50 nm to about 100 nm.

13. The non-planar semiconductor structure of claim 11, wherein trenches are present in center portions of the filler material layer, exposing the one or more raised semiconductor structures, the semiconductor structure further comprising silicide on the exposed one or more raised semiconductor structures.

14. The non-planar semiconductor structure of claim 13, wherein the silicide has a thickness of about 9 nm to about 12 nm.

15. The non-planar semiconductor structure of claim 13, further comprising a bottom contact portion comprising contact material conformally situated on the silicide.

16. The non-planar semiconductor structure of claim 15, wherein the bottom contact portion has a thickness of about 10 nm to about 40 nm.

17. The non-planar semiconductor structure of claim 15, wherein the conformal contact material comprises tungsten.

18. The non-planar semiconductor structure of claim 15, further comprising a contact body of the conformal contact material connected to the bottom contact portion, wherein the contact body has a roughly V-shape, and wherein the bottom contact portion is wider than the contact body where the bottom contact portion and contact body meet.

19. The non-planar semiconductor structure of claim 18, wherein the bottom contact portion has a thickness of about 10 nm to about 40 nm, and wherein the conformal contact material comprises tungsten.

20. The non-planar semiconductor structure of claim 11, further comprising at least one epitaxial structure on at least one of the one or more raised semiconductor structures, wherein the layer of filler material is above the at least one epitaxial structure.
